(19) United States
(12) Patent Application Publication
(10) Pub. No.: US 2022/0384614 A1
(43) Pub. Date: Dec. 1, 2022

(54) SEMICONDUCTOR DEVICE AND METHOD FOR MANUFACTURING STRUCTURE

(71) Applicants: SCIOCS COMPANY LIMITED, Hitachi-shi, Ibaraki (JP); SUMITOMO CHEMICAL COMPANY, LIMITED, Tokyo (JP)

(72) Inventors: Osamu ICHIKAWA, Hitachi-shi (JP); Fumimasa HORIKIRI, Hitachi-shi (JP); Noboru FUKUHARA, Hitachi-shi (JP)

(73) Assignees: SCIOCS COMPANY LIMITED, Hitachi-shi, Ibaraki (JP); SUMITOMO CHEMICAL COMPANY, LIMITED, Tokyo (JP)

(21) Appl. No.: 17/776,143

(22) PCT Filed: Oct. 9, 2020
(86) PCT No.: PCT/JP2020/038332

§ 371 Date: May 11, 2022

(30) Foreign Application Priority Data
Nov. 13, 2019 (JP) 2019-205235

(51) Int. Cl. H01L 29/66; H01L 29/20; H01L 29/778; H01L 21/3063

(52) U.S. Cl. CPC H01L 29/66462; H01L 29/2003; H01L 29/7786; H01L 21/30635

(57) ABSTRACT

There is provided a semiconductor device, including: a substrate; a group III nitride layer on the substrate, the group III nitride layer containing group III nitride; and a recess on the group III nitride layer, the group III nitride layer including: a channel layer, and a barrier layer on the channel layer, thereby forming a two-dimensional electron gas in the channel layer, the barrier layer including: a first layer containing aluminum gallium nitride, and a second layer on the first layer, the second layer containing aluminum gallium nitride added with an n-type impurity, wherein the recess is formed by removing all or a part of a thickness of the second layer, and at least a part of a thickness of the first layer is arranged below the recess.

### TECHNICAL FIELD

The present disclosure relates to a semiconductor device and a method for manufacturing a structure.

### DESCRIPTION OF RELATED ART

Group III nitride is used as a material for manufacturing a semiconductor device such as a high electron mobility transistor (HEMT). A technique for forming a recess (gate recess) in a region where a gate electrode is formed, has been proposed as a technique for normally off the HEMT in which group III nitride is used.

Photoelectrochemical (PEC) etching has been proposed as a new technique for etching the group III nitride (see, for example, Non-Patent Document 1). The PEC etching is wet etching with less damage than general dry etching, and it is preferable in that an apparatus is simpler than special dry etching with less damage such as neutral particle beam etching (see, for example, Non-Patent Document 2) and atomic layer etching (see, for example, Non-Patent Document 3).

### PRIOR ART DOCUMENT

### Non-Patent Literature

[Non-Patent Document 1] J. Murata et al., “Photo-electrochemical etching of free-standing GaN wafer surfaces grown by hydride vapor phase epitaxy”, Electrochimica Acta 171 (2015) 89-95
[Non-Patent Document 2] S. Samukawa, JJAP, 45 (2006) 2395.
[Non-Patent Document 3] T. Faraz, ECS J. Solid Stat. Scie. & Technol., 4, N5023 (2015).

### SUMMARY OF THE DISCLOSURE

### Problem to be Solved by the Disclosure

An object of the present disclosure is to provide a suitable technique for forming a recess (gate recess) by PEC etching in a semiconductor device (HEMT) in which group III nitride is used.

### Means for Solving the Problem

According to an aspect of the present disclosure, there is provided a semiconductor device, including:

a substrate;

a group III nitride layer on the substrate, the group III nitride layer containing group III nitride; and

a recess on the group III nitride layer,

the group III nitride layer including:

a channel layer, and

a barrier layer on the channel layer, thereby forming a two-dimensional electron gas in the channel layer,

the barrier layer including:

a first layer containing aluminum gallium nitride, and

a second layer on the first layer, the second layer containing aluminum gallium nitride added with an n-type impurity,

wherein the recess is formed by removing all or a part of a thickness of the second layer, and at least a part of a thickness of the first layer is arranged below the recess.

According to another aspect of the present disclosure, there is provided a method for manufacturing a structure,

the structure including:

a laminated structure of

a first layer containing aluminum gallium nitride and a second layer on the first layer, the second layer containing aluminum gallium nitride added with an n-type impurity, and

a recess on the laminated structure,

wherein the recess is formed by removing all or a part of a thickness of the second layer, and at least a part of a thickness of the first layer is arranged below the recess,

the method including:

forming the recess by etching the second layer by photoelectrochemical etching, with the first layer as an etching stopper.

### Advantage of the Disclosure

There is provided a suitable technique for forming a recess (gate recess) by PEC etching in a semiconductor device (HEMT) in which group III nitride is used.

### BRIEF DESCRIPTION OF THE DRAWINGS

FIG. 1(a) is a schematic cross-sectional view illustrating HEMT according to an embodiment of the present disclosure, and FIG. 1(b) is a schematic cross-sectional view illustrating a wafer used as a material for the HEMT according to an embodiment of the present disclosure.

FIG. 2(a) is a schematic cross-sectional view illustrating an etching target according to an embodiment, and FIG. 2(b) is a schematic cross-sectional view of a PEC etching apparatus illustrating a PEC etching step.

FIG. 3(a) is a schematic cross-sectional view illustrating an etching target according to an embodiment, in a state in which the PEC etching step is completed, and FIG. 3(b) is a schematic cross-sectional view of a flattening etching apparatus, illustrating a flattening etching step.

FIG. 4 is a schematic cross-sectional view illustrating an etching target according to an embodiment, in a state in which the flattening etching step is completed.

FIG. 5(a) is a graph showing a relationship between an etching time and an etching depth of the PEC etching according to an experimental example, and FIG. 5(b) is an AFM image of a surface of an epi layer according to an experimental example.

FIG. 6(a) is an AFM image of an unflattened bottom surface according to an experimental example, and FIG. 6(b) is an AFM image of a flattened bottom surface according to an experimental example.

FIG. 7 is a cross-sectional image of the epi layer in which the recess according to the experimental example is formed, observed with TEM.

FIG. 8 is an example of a SIMS profile of Al composition and n-type impurity concentration (Si concentration) in the vicinity of a barrier layer.

### DETAILED DESCRIPTION OF THE DISCLOSURE

### Embodiment

A semiconductor device 200 according to an embodiment of the present disclosure will be described. Specifically, the semiconductor device 200 is a high electron mobility transistor (HEMT). The semiconductor device 200 is also referred to as HEMT 200. As described below, HEMT 200 according to the present embodiment has a recess 110 formed by photoelectrochemical (PEC) etching, as a recess (gate recess) 110 where a gate electrode 212 is arranged.

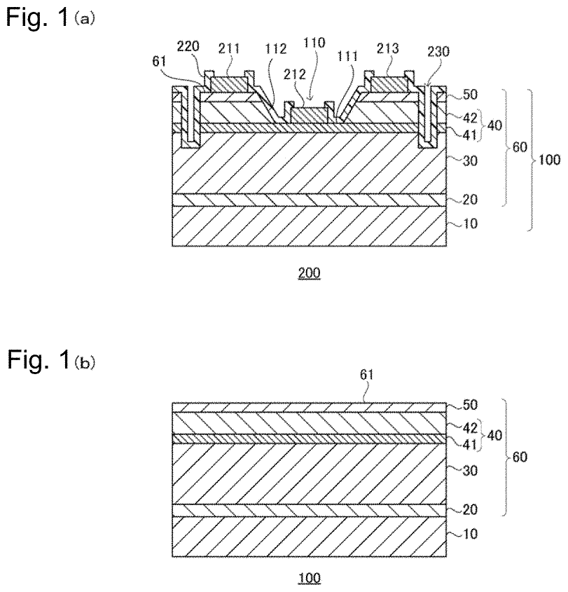

First, a structure of the HEMT 200 and a group III nitride laminated substrate 100 (hereinafter, also referred to as a wafer 100) used as a material of the HEMT 200, will be described. FIG. 1(a) is a schematic cross-sectional view illustrating the HEMT 200, and FIG. 1(b) is a schematic cross-sectional view illustrating the wafer 100. FIG. 1(a) exemplifies one HEMT 200 formed in a large number in a plane of the wafer 100.

The wafer 100 has a substrate 10 and a group III nitride layer 60 (hereinafter, also referred to as an epi layer 60) formed by epitaxial growth on the substrate 10 and containing group III nitride.

As the substrate 10, for example, a semi-insulating silicon carbide (SiC) substrate is used. Here, the “semi-insulating” means, for example, a state in which a specific resistance is 10⁵ Ωcm or more. A substrate in which a thick semi-insulating epi layer is formed on a conductive substrate (for example, a substrate in which a carbon (C)-doped semi-insulating GaN layer having a thickness of 10 μm is formed on an n-type conductive gallium nitride (GaN) substrate), may be used as the semi-insulating substrate 10. The substrate 10 is not limited to the SiC substrate, and other substrates (sapphire substrate, silicon (Si) substrate, (semi-insulating) GaN substrate, etc.) may be used. The laminated structure of the epi layer 60 may be appropriately selected depending on a type of the substrate 10, characteristics of the HEMT 200 to be obtained, and the like.

As the epi layer 60 when a SiC substrate is used as the substrate 10, for example, a laminated structure of a nucleation layer 20 containing aluminum nitride (AlN), a thick channel layer 30 containing gallium nitride (GaN), a barrier layer 40 containing gallium nitride (AlGaN), and a cap layer 50 containing GaN, is used. The cap layer 50 may be omitted.

The epi layer 60 constituting the HEMT 200 has at least a channel layer 30 and a barrier layer 40 formed on the channel layer. By being formed on the channel layer 30, the barrier layer 40 forms a two-dimensional electron gas (2DEG) that becomes a channel of the HEMT 200, in the vicinity of a top surface of the channel layer 30.

The barrier layer 40 according to the present embodiment has a laminated structure of a lower layer 41 containing AlGaN and an upper layer 42 formed on the lower layer 41 (immediately on the lower layer 41) and containing AlGaN added with an n-type impurity.

The lower layer 41 is configured as a non-conductive layer, and preferably contains i-type AlGaN not intentionally added with an impurity (particularly conductive impurity). Hereinafter, the lower layer 41 is also referred to as an i-type layer 41. The lower layer 41 contains at least AlGaN having a lower n-type impurity concentration than the upper layer 42. In order to suppress a conductivity of the i-type layer 41, the concentration of the n-type impurity in the i-type layer 41 is preferably less than 5×10¹⁶/cm³, and more preferably less than 1×10¹⁶/cm³. Here, regarding the lower layer 41, “non-conductive” means having lower conductivity than the upper layer 42, and preferably means that the concentration of the n-type impurity is suppressed as described above.

The upper layer 42 is configured as a conductive layer, and preferably contains n-type AlGaN having conductivity by adding an n-type impurity. Hereinafter, the upper layer 42 is also referred to as an n-type layer 42. In order to obtain appropriate conductivity of the n-type layer 42, the concentration of the n-type impurity in the n-type layer 42 is preferably 1×10⁷/cm³ or more. Further, in order to suppress a decrease in crystallinity of the n-type layer 42, the concentration of the n-type impurity in the n-type layer 42 is preferably less than 1×10¹⁹/cm³.

Here, the concentration of the n-type impurity of the i-type layer 41 is defined as, for example, a total concentration of a silicon (Si) concentration and a germanium (Ge) concentration in the i-type layer 41. Further, the concentration of the n-type impurity of the n-type layer 42 is defined as, for example, a total concentration of a Si concentration and a Ge concentration in the n-type layer 42. The concentration of the n-type impurity of the i-type layer 41 is defined as, for example, an average concentration of the n-type impurity concentration in a total thickness of the i-type layer 41. Further, the concentration of the n-type impurity in the n-type layer 42 is defined as, for example, an average concentration in a total thickness of the n-type layer 42.

Al composition x in AlₓGa₁₋ₓN constituting the i-type layer 41 is, for example, 0.1≤x≤0.3, and similarly, Al composition y in Al_{y}Ga_{1-y}N constituting the n-type layer 42 is, for example, 0.1≤x≤0.3. It is preferable that the Al composition x of the i-type layer 41 and the Al composition y of the n-type layer 42 are at least equivalent in the vicinity of an interface between the i-type layer 41 and the n-type layer 42, from a viewpoint of suppressing a formation of unnecessary 2DEG at an interface between the i-type layer 41 and the n-type layer 42, etc. The fact that the Al composition x of the i-type layer 41 and the Al composition y of the n-type layer 42 are equivalent at least in the vicinity of the interface between the i-type layer 41 and the n-type layer 4, means that a difference between the Al composition x and the Al composition y (an absolute value of the difference) is preferably 0.01 or less. The Al composition x of the i-type layer 41 and the Al composition y of the n-type layer 42 in the vicinity of the interface are defined as, for example, an average Al composition at a thickness of 1 nm from the interface, respectively.

It is preferable that an overall thickness of the barrier layer 40, i.e., a combined thickness of the i-type layer 41 and the n-type layer 42 is, for example, 10 nm or more so that 2DEG is formed at an appropriately high concentration. Further, an overall thickness of the barrier layer 40 is preferably, for example, 100 nm or less so that a crystallinity of the barrier layer 40 heteroepitaxially grown on the channel layer 30 does not deteriorate.

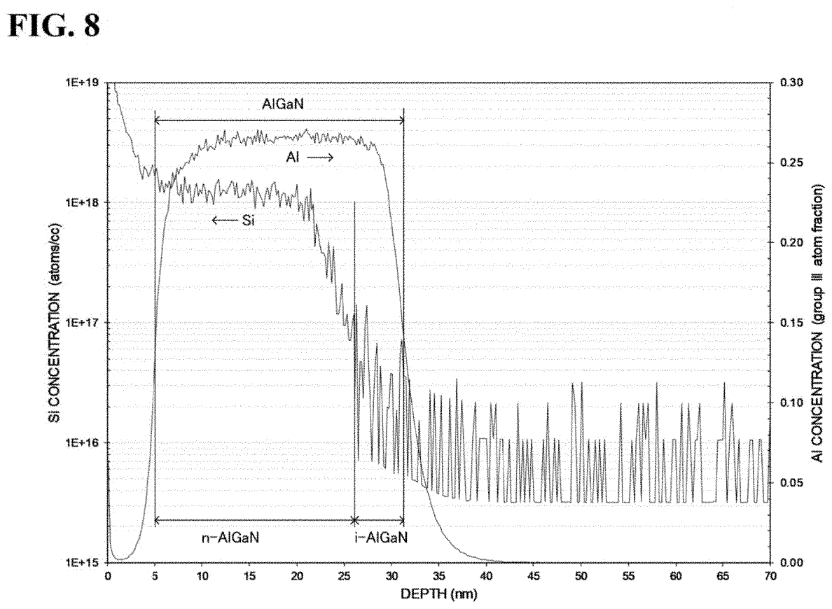

As will be described later, a bottom surface 111 of the recess 110 is arranged in the vicinity of the top surface of the i-type layer 41. That is, a thickness of the i-type layer 41 generally corresponds to a remaining thickness of the barrier layer 40 below the recess 110 which is a gate recess. The thickness of the i-type layer 41 is appropriately set to a thickness such that the HEMT 200 can be normally turned off, and is preferably 10 nm or less, for example. Further, the thickness of the i-type layer 41 is appropriately set to a thickness so that a remaining thickness of the barrier layer 40 below the recess 110 is stably secured and is preferably 2 nm or more, for example. An arrangement portion of the i-type layer 41 may be determined as follows, using secondary ion mass spectrometry (SIMS) for example. For example, a position where the Al composition is halved on the channel layer 30 side with respect to a bulk Al composition (a portion not in the vicinity of upper and lower interfaces) in the barrier layer 40, may be determined to be a boundary between the i-type layer 41 and the channel layer (GaN layer) 30, that is, it may be determined to be a lower end of the i-type layer 41. Further, for example, a position where the concentration of the n-type impurity decreasing from the n-type layer 42 side is less than 5×10¹⁶/cm³ in the vicinity of the interface between the n-type layer 42 and the i-type layer 41, may be determined to be the interface (boundary) between the n-type layer 42 and the i-type layer 41, that is, it may be determined to be an upper end of the i-type layer 41. FIG. 8 illustrates an example of SIMS profile of the Al composition and the n-type impurity concentration (here, Si concentration) in the vicinity of the barrier layer 40. The barrier layer 40 is referred to as “AlGaN”, the i-type layer 41 is referred to as “i-AlGaN”, and the n-type layer 42 is referred to as “n-AlGaN”.

The thickness of the n-type layer 42 approximately corresponds to a difference between a depth of the recess 110 which is the gate recess, that is, the thickness of the barrier layer 40 below a source electrode 211 and a drain electrode 213, and the thickness of the barrier layer 40 below the gate electrode 212. The thickness of the n-type layer 42 is appropriately set to a thickness at which the difference is appropriate, and is preferably 5 nm or more, for example. Further, the thickness of the n-type layer 42 is appropriately set so that an overall thickness of the barrier layer 40 does not become excessively thick (for example, 100 nm or less as described above), and is preferably 90 nm or less.

The cap layer 50 is configured as a conductive layer, and for example, contains GaN added with an n-type impurity, thereby having conductivity. The thickness of the cap layer 50 is appropriately set as needed, and is, for example, 5 nm.

In the laminated structure of the barrier layer 40 and the cap layer 50, the i-type layer 41 is configured as a non-conductive layer, and a laminated portion of the n-type layer 42 and the cap layer 50 is configured as a conductive layer.

The present embodiment is an embodiment in which a surface 61 of the epi layer 60 contains a c-plane of the group III nitride constituting the epi layer 60d. Here, a phrase “contains a c-plane” means that a crystal plane having a lowest index closest to the surface 61 is the c-plane of the group III nitride crystal constituting the epi layer 60. The group III nitride constituting the epi layer 60 has dislocations (through dislocations), and the dislocations are distributed at a predetermined density on the surface 61.

The HEMT 200 includes: the epi layer 60 of the wafer 100 (at least, the channel layer 30 and the barrier layer 40 which are operating layers through which an operating current flows in the HEMT 200), and a source electrode 211, a gate electrode 212 and a drain electrode 213. Further, the HEMT 200 according to the present embodiment has a recess 110 formed on the epi layer 60, more specifically on the barrier layer 40.

The recess 110 is formed on the surface (top surface) 61 of the epi layer 60, and is formed by removing a part of the thickness of the barrier layer 40 (and also is formed by removing an overall thickness of a cap layer 50 when the epi layer 60 has the cap layer 50). The recess 110 is formed by removing an overall thickness or a part of the n-type layer 42 (upper layer of the barrier layer 40), and at least a part of the thickness of the i-type layer (lower layer of the barrier layer 40) 41 is arranged below the recess 110.

As will be described in detail later, the recess 110 is formed by etching the barrier layer 40 by PEC etching. In this PEC etching, by etching the n-type layer 42, with the i-type layer 41 as an etching stopper, the recess 110 in which the bottom surface 111 is arranged near the top surface of the i-type layer 41 is formed. As a typical (ideal) embodiment, FIG. 1(a) exemplifies an embodiment in which a position of the bottom surface 111 of the recess 110 in a depth direction coincides with a position of the top surface of the i-type layer 41, that is, an embodiment in which the recess 110 is formed by removing the overall thickness of the n-type layer 42, and the overall thickness of the i-type layer 41 is arranged below the recess 110.

The gate electrode 212 is formed on the bottom surface 111 of the recess 110. The source electrode 211 and the drain electrode 213 are formed on the surface 61 of the epi layer 60. The gate electrode 212 is formed, for example, by a Ni/Au layer in which a gold (Au) layer is laminated on a nickel (Ni) layer. Each of the source electrode 211 and the drain electrode 213 is formed by, for example, a Ti/Al/Au layer in which an Al layer is laminated on a titanium (Ti) layer and an Au layer is further laminated on the Al layer.

The HEMT 200 may further include a protective film 220 and an element separation region 230. The protective film 220 is formed so as to have an opening on a top surface of the source electrode 211, the gate electrode 212, and the drain electrode 213. The element separation region 230 separates between adjacent HEMTs 200 (between individual elements). As the element separation region 230, for example, an element separation groove is formed, and the element separation groove is formed so that the bottom surface thereof is arranged at a position deeper than the top surface of the channel layer 30, that is, 2DEG is divided by the element separation groove 230 between adjacent elements. Not limited to the element separation groove, the element separation region 230 may be formed by, for example, ion implantation.

Next, a method for manufacturing the HEMT 200 will be described exemplary. In the method for manufacturing the HEMT 200, a step of forming the recess 110 by PEC etching (hereinafter, also referred to as a PEC etching step) is performed.

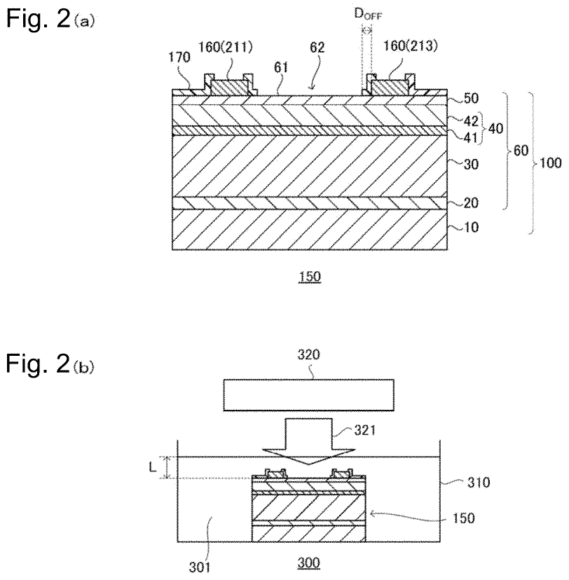

Prior to the PEC etching step, a structure 150 (hereinafter, also referred to as an etching target 150) to be a target of the PEC etching processing is prepared. FIG. 2(a) is a schematic cross-sectional view illustrating the etching target 150.

The etching target 150 has a structure in which a cathode pad 160 and a mask 170 are provided on the epi layer 60 of the wafer 100. The present embodiment is an embodiment in which the cathode pad 160 is used as (at least one of) the source electrode 211 and the drain electrode 213 of the HEMT 200, that is, an embodiment in which (at least one of) the source electrode 211 and the drain electrode 213 of the HEMT 200 is used as the cathode pad 160. Specifically for example, the etching target 150 has a structure in which a mask 170 for PEC etching is formed on a member at a stage where the source electrode 211 and the drain electrode 213 are formed on the surface 61 of the epi layer 60.

The mask 170 has an opening in a region 62 (hereinafter, also referred to as a region 62 to be etched) formed on the surface 61 of the epi layer 60 and where the recess 110 should be formed, and an opening that exposes the top surface of the cathode pad 160 (the source electrode 211 and the drain electrode 213). The mask 170 contains a non-conductive material such as resist, silicon oxide and the like.

The cathode pad 160 is a conductive member formed from conductive materials, and is provided so as to be in contact with at least a part of a surface of a conductive region (of the epi layer 60) of the wafer 100, which is electrically connected to the region 62 to be etched.

FIG. 2(b) is a schematic cross-sectional view of a PEC etching apparatus 300, illustrating a PEC etching step. The PEC etching apparatus 300 includes a container 310 for accommodating an etching solution 301, and a light source 320 for emitting ultraviolet (UV) light 321.

In the PEC etching step, the etching target 150 is immersed in the etching solution 301, and the surface 61 of the epi layer 60 is irradiated with UV light 321 through the etching solution 301, in a state where the region 62 to be etched and the cathode pad 160 (at least a part of the cathode pad 160, for example, the top surface) are in contact with the etching solution 301.

In this way, the recess 110 is formed by PEC-etching the group III nitride constituting the region 62 to be etched. More specifically, the recess 110 is formed by PEC etching (the overall thickness of the cap layer 50 when the cap layer 50 is present, and) the thickness of a part of the barrier layer 40.

Here, a mechanism of the PEC etching will be described, and the etching solution 301, the cathode pad 160, and the like will be described in more detail. First, the PEC etching mechanism will be described by taking GaN etching as an example.

As the etching solution 301 for PEC etching, an alkaline or acidic etching solution 301 is used, the alkaline or acidic etching solute 301 containing oxygen used to generate an oxide of a group III element contained in the group III nitride that constitutes a region 62 to be etched (meaning a bottom surface 111 after the recess 110 has begun to be formed), and further containing an oxidizer that receives electrons.

As the oxidizer, peroxodisulfuric acid ion (S₂O₈²⁻) is exemplified. Hereinafter, an embodiment in which S₂O₈²⁻ is supplied from potassium persulfate (K₂S₂O₈) will be exemplified. However, S₂O₈²⁻ may be supplied from other element such as peroxodisulfate (NaSO), ammonium peroxodisulfate (ammonium persulfate, (NH₄)₂S₂O₈), etc.

As a first example of the etching solution 301, there is an example in which potassium hydroxide (KOH) aqueous solution and potassium persulfate (K₂S₂O₈) aqueous solution are mixed and show alkalinity at the start of PEC etching. Such an etching solution 301 is prepared, for example, by mixing 0.01M KOH aqueous solution and 0.05M K₂S₂O₈ aqueous solution at a mixing ratio of 1:1. The concentration of the KOH aqueous solution, the concentration of the K₂S₂O₈ aqueous solution, and the mixing ratio of these aqueous solutions may be appropriately adjusted as needed. The etching solution 301, which is a mixture of the KOH aqueous solution and the K₂S₂O₈ aqueous solution, can show acidity at the start of PEC etching, for example, by lowering the concentration of the KOH aqueous solution.

A PEC etching mechanism when the etching solution 301 of the first example is used, will be described. By irradiating the surface 61 to be PEC-etched with UV light 321 having a wavelength of 365 nm or less, holes and electrons are generated in pairs in the GaN constituting the region 62 to be etched. The generated holes decompose GaN into Ga³⁺ and N₂ (Chemical formula 1), and further, Ga³⁺ is oxidized by hydroxide ions (OH⁻) to generate gallium oxide (Ga₂O₃) (Chemical formula 2). Then, the generated Ga₂O₃ is dissolved in an alkali (or acid). In this way, PEC etching of GaN is performed. Oxygen is generated when the generated holes react with water and the water is decomposed (Chemical formula 3).

$$GaN ( s ) + 3 {h}^{+} \to {Ga}^{3 +} + \frac{1}{2} {N}_{2} ( g ) ↑ \qquad [ Chemical formula 1 ]$$

$${Ga}^{3 +} + 3 {OH}^{-} \to \frac{1}{2} {Ga}_{2} {O}_{3} ( s ) + \frac{3}{2} {H}_{2} O ( I ) \qquad [ Chemical formula 2 ]$$

$${H}_{2} O ( I ) + 2 {h}^{+} \to \frac{1}{2} {O}_{2} ( g ) ↑ + 2 {H}^{+} \qquad [ Chemical formula 3 ]$$

Further, dissolution of K₂S₂O₈ in water produces peroxodisulfate ion (S₂O₈²⁻) (Chemical formula 4), and irradiation of S₂O₈²⁻ with UV light 321 produces sulfate ion radicals (SO₄⁻* radicals) (Chemical Formula 5). The electrons generated in pairs with the holes react with water together with SO₄⁻* radicals to decompose the water. This produces hydrogen (Chemical formula 6). Thus, in the PEC etching of the present embodiment, by using SO₄⁻* radicals, electrons generated in pairs with holes in GaN can be consumed, so that PEC etching can progress satisfactorily. As shown in (Chemical formula 6), as the sulfate ion (SO₄²⁻) increases with a progress of PEC etching, the acidity of the etching solution 301 becomes stronger (pH decreases).

K₂S₂O₈⁻→2K⁺+S₂O₈²⁻ [Chemical formula 4]

S₂O₈²⁻+heat or hv→2SO₄⁻* [Chemical formula 5]

2SO₄⁻*+2e⁻+2H₂O(I)→2SO₄²⁻+2HO*+H₂(g)↑ [Chemical formula 6]

As a second example of the etching solution 301, there is an example in which phosphoric acid (H₃PO₄) aqueous solution and potassium persulfate (K₂S₂O₈) aqueous solution are mixed and show acidity at the start of PEC etching. Such an etching solution 301 is prepared, for example, by mixing 0.01M H₃PO₄ aqueous solution and 0.05M K₂S₂O₈ aqueous solution at a mixing ratio of 1:1. The concentration of the H₃PO₄ aqueous solution, the concentration of the K₂S₂O₈ aqueous solution, and the mixing ratio of these aqueous solutions may be appropriately adjusted as needed. Since both the H₃PO₄ aqueous solution and the K₂S₂O₈ aqueous solution are acidic, the etching solution 301 in which the H₃PO₄ aqueous solution and the K₂S₂O₈ aqueous solution are mixed, is acidic at an arbitrary mixing ratio. Since the K₂S₂O₈ aqueous solution itself is acidic, only the K₂S₂O₈ aqueous solution may be used as the etching solution 301 which is acidic at the start of etching. In this case, the concentration of the K₂S₂O₈ aqueous solution may be, for example, 0.025M.

It is preferable that the etching solution 301 is acidic from the start of PEC etching from a viewpoint of facilitating the use of the resist as the mask 170. This is because the resist mask is easily peeled off when the etching solution 301 is alkaline. When silicon oxide is used as the mask 170, there is no particular problem whether the etching solution 301 is acidic or alkaline.

In the PEC etching mechanism when the etching solution 301 of the second example is used, it is presumed that (Chemical formula 1) to (Chemical formula 3) described in the case of using the etching solution 301 of the first example are replaced with (Chemical formula 7). That is, Ga₂O₃, hydrogen ions (H⁺), and N₂ are generated by the reaction of GaN, holes generated by irradiation with UV light 321 and water (Chemical formula 7). Then, the generated Ga₂O₃ is dissolved in an acid. In this way, PEC etching of GaN is performed. The mechanism in which the electrons generated in pairs with the holes are consumed by S₂O₈²⁻ as shown in (Chemical formula 4) to (Chemical formula 6) is the same as in the case of using the etching solution 301 of the first example.

$$GaN ( s ) + 3 {h}^{+} + \\ \frac{3}{2} {H}_{2} O ( I ) \to \frac{1}{2} {Ga}_{2} {O}_{3} ( s ) + 3 {H}^{+} + \frac{1}{2} {N}_{2} ( g ) ↑ \qquad [ Chemical formula 7 ]$$

As understood from (Chemical 1) and (Chemical 2), or (Chemical 7), the region 62 to be etched (the bottom surface 111 of the recess 110) where PEC etching occurs is considered to function as an anode in which the holes are consumed. Further, as understood from (Chemical 6), the surface of the cathode pad 160, which is a conductive member electrically connected to the region 62 to be etched, in contact with the etching solution 301, is considered to function as a cathode in which electrons are consumed (emitted).

When the cathode pad 160 is not provided, it becomes difficult to secure a region that functions as a cathode, and it becomes difficult to progress PEC etching. In the present embodiment, by providing the cathode pad 160, PEC etching can progress satisfactorily. Further, with the mask 170 having an opening on the top surface of the cathode pad 160, that is, by allowing a large area on the top surface of the cathode pad 160 to function as a cathode, PEC etching can progress more satisfactorily.

As shown in (Chemical formula 5), as a method for generating SO₄⁻* radicals from S₂O₈²⁻, at least one of irradiation of UV light 321 and heating can be used. When irradiation with UV light 321 is used, in order to increase a light absorption by S₂O₈²⁻ and efficiently generate SO₄⁻* radicals, it is preferable that a wavelength of the UV light 321 is 200 nm or more and less than 310 nm. That is, from a viewpoint of efficiently generating holes in the group III nitride in the epi layer 60 and generating SO₄⁻* radicals from S₂O₈²⁻ in the etching solution 301 by irradiation with UV light 321, the wavelength of the UV light 321 is preferably 200 nm or more and less than 310 nm. When the generation of SO₄⁻* radicals from S₂O₈²⁻ occurs by heating, the wavelength of the UV light 321 may be 310 nm or more (at 365 nm or less).

When generating SO₄⁻* radicals from S₂O₈²⁻ by irradiation with UV light 321, a distance (wafer placement depth) L (see FIG. 2(b)) from the surface 61 of the epi layer 60 (of the wafer 100) to the top surface of the etching solution 301, is preferably 1 mm or more and 100 mm or less, for example. When the distance L is excessively short, for example, less than 1 mm, an amount of SO₄* radicals generated in the etching solution 301 above the wafer 100 may become unstable due to a fluctuation of the distance L. When the distance L is short, it becomes difficult to control a height of a liquid level, and therefore the distance L is preferably 1 mm or more, more preferably 3 mm or more, and further preferably 5 mm or more. Further, when the distance L is excessively long, for example, beyond 100 mm, a large amount of SO₄⁻* radicals that do not contribute to PEC etching are unnecessarily generated in the etching solution 301 above the wafer 100, and therefore a utilization efficiency of the etching solution 301 is reduced.

The surface 61 of the epi layer 60 (of the wafer 100) is preferably arranged parallel (horizontally) to the surface of the etching solution 301. Further, the UV light 321 preferably irradiates the surface 61 of the epi layer 60 vertically. In order to form a large number of elements in a plane of the wafer 100, a plurality of regions 62 to be etched separated from each other are arranged over an entire surface of the wafer 100. By arranging the surface 61 of the epi layer 60 in parallel with the surface of the etching solution 301 and irradiating the surface 61 of the epi layer 60 vertically with UV light 321, the uniformity of light irradiation conditions for each region 62 to be etched, can be improved.

Irradiation of the surface 61 of the epi layer 60 with the UV light 321 is preferably performed in a state where the wafer 100 and the etching solution 301 are stationary, that is, without stirring the etching solution 301. Thereby, a supply state of SO₄⁻* radicals supplied to each region 62 to be etched can be prevented from fluctuating due to a movement of the etching solution 301, and SO₄⁻* radicals can be appropriately supplied to each region 62 to be etched by diffusion. Thereby, the uniformity of the etching conditions (uniformity between separated regions 62 to be etched) and the flatness of etching in each region 62 to be etched, can be improved. If necessary, a stationary waiting step may be provided before irradiating the surface 61 of the epi layer 60 with the UV light 321 to wait for the etching solution 301 to be stationary.

The present inventors obtain a finding such that when an edge of the mask used for PEC etching contains a conductive material, the shape of the edge of the recess formed by PEC etching tends to be a disordered shape that does not follow the edge of the mask (along the edge of the mask), and since the edge of the mask contains a non-conductive material, it is easy to control the shape of the edge of the recess formed by PEC etching to the shape along the edge of the mask. Accordingly, the mask edge defining the region 62 to be etched (ie, the edge of the recess 110) is preferably defined by a mask 170 containing a non-conductive material. It is preferable that the cathode pad 160 is arranged (in a plan view) away from the edge of the recess 110 (at a position that does not define the edge of the recess 110). From a viewpoint of satisfactorily controlling the shape of the edge of the recess 110, a distance D_{OFF} (see FIG. 2(a)) between the edge of the mask 170 and the edge of the cathode pad 160 (in a plan view) is preferably 5 μm or more, and more preferably 10 μm or more.

PEC etching can also be performed to a group III nitride other than the exemplified GaN. The group III element contained in the group III nitride may be at least one of aluminum (Al), gallium (Ga) and indium (In). The concept of PEC etching for the Al component or In component in the group III nitride is the same as the concept described for the Ga component with reference to (Chemical formula 1) and (Chemical formula 2), or (Chemical formula 7). That is, PEC etching can be performed by forming holes by irradiation with UV light 321 to generate an oxide of Al or an oxide of In, and dissolving these oxides in an alkali or an acid. The wavelength of the UV light 321 (of the light 321) may be appropriately changed depending on the composition of the group III nitride to be etched. When Al is contained based on PEC etching of GaN, light having a shorter wavelength may be used, and when In is contained, light having a longer wavelength can also be used. That is, light having a wavelength that allows the group III nitride to be PEC-etched can be appropriately selected and used, depending on the composition of the group III nitride to be processed.

In the etching target 150 of the present embodiment, the region 62 to be etched (bottom surface 111 of the recess 110), which is an anode, and the cathode pad 160, which is a cathode, can be electrically connected in the in-plane direction, through the conductive cap layer 50 and n-type layer 42 which are conductive. The cap layer 50 is PEC-etched by conducting the region 62 to be etched and the cathode pad 160 through the cap layer 50 and the n-type layer 42, and after the overall thickness of the cap layer 50 is etched, the n-type layer 42 is PEC-etched due to a further conduction through the n-type layer 42.

When the PEC etching progresses and the n-type layer 42 is etched to overall thickness, the conduction between the region to be etched 62 (bottom surface 111 of the recess 110) and the cathode pad 160 is hindered, thereby making the PEC etching stop, with the non-conductive i-type layer 41 remaining below the recess 110. As described above, in the present embodiment, with the i-type layer 41 as an etching stopper, the PEC etching can be automatically stopped, and the formation of the recess 110 can be completed.

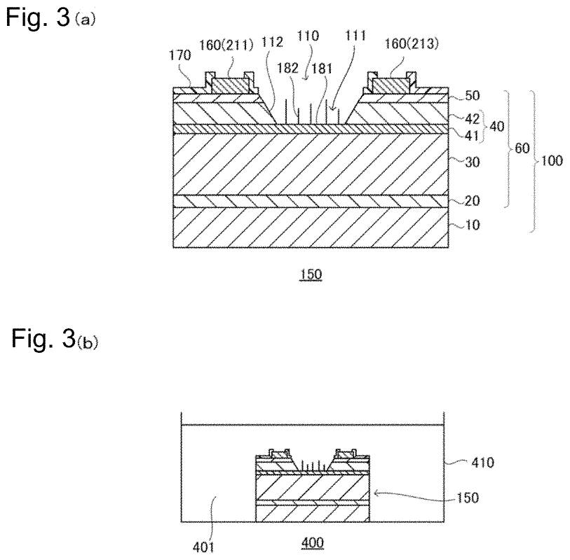

FIG. 3(a) is a schematic cross-sectional view of the etching target 150, illustrating a state in which the PEC etching step is completed. As described above, the dislocations are distributed at a predetermined density on the surface 61 of the epi layer 60. In the dislocations, PEC etching is unlikely to occur because a hole lifetime is short. Therefore, a protrusion 182 is likely to be formed as an undissolved portion in the PEC etching at a position corresponding to a dislocation on the bottom surface 111 of the recess 110. That is, a flat portion 181 (a portion where PEC etching has progressed without dislocations) and a protrusion 182 that is raised with respect to the flat portion 181 because PEC etching is less likely to occur than the flat portion 181, are formed on the bottom surface 111 of the recess 110. Since the protrusion 182 is an undissolved portion in the PEC etching, its height is at most a depth of the recess 110 or less.

In the recess 110 formed in the PEC etching step, the protrusion 182, which is the undissolved portion in the PEC etching, is likely to be formed in this way. Therefore, etching for improving the flatness of the bottom surface 111 by removing the protrusion 182 is preferably performed after the PEC etching step (hereinafter, also referred to as a flattening etching step). In the flattening etching step, specifically, the protrusion 182 is lowered by etching the protrusion 182 (selectively with respect to the flat portion 181) by flattening etching.

For example, wet etching (not PEC etching) is used as the flattening etching, in which an acidic or alkaline etching solution is used. As an etching solution for the flattening etching, for example, hydrochloric acid (HCl) aqueous solution, mixed aqueous solution (hydrochloric acid hydrogen peroxide) of hydrochloric acid (HCl) and hydrogen peroxide (H₂O₂), mixed aqueous solution (piranha solution) of sulfuric acid (H₂SO₄) and hydrogen peroxide (H₂O₂), tetramethylammonium hydroxide (TMAH) aqueous solution, hydrofluoric acid aqueous solution (hydrofluoric acid), potassium hydroxide (KOH) aqueous solution, etc., can be used.

An epi layer 60 heteroepitaxially grown on a substrate 10 which is a heterogeneous substrate such as a SiC substrate, a sapphire substrate, a Si substrate, etc., has a high dislocation density of, for example, 1×10⁸/cm² or more. Therefore, when the substrate 10 which is a different type of substrate is used, the protrusion 182 is likely to be formed by the PEC etching in the PEC etching step. Accordingly, it is particularly preferable to flatten the bottom surface 111 by the flattening etching step.

FIG. 3(b) is a schematic cross-sectional view of a flattening etching apparatus 400, illustrating the flattening etching step. The flattening etching apparatus 400 has a container 410 for accommodating an etching solution 401. In the flattening etching step, the protrusion 182 is etched by immersing the etching target 150 in the etching solution 401 so that the recess 110 comes into contact with the etching solution 401. Thereby, the bottom surface 111 of the recess 110 is flattened. The flattening etching is not PEC etching. Therefore, in the flattening etching step, the surface 61 of the epi layer 60 is not irradiated with UV light (the surface 61 of the epi layer 60 does not need to be irradiated with UV light).

It is known that it is difficult to etch the c-plane (+c-plane) of the group III nitride such as GaN, but the group III nitride can be PEC-etched regardless of a crystal orientation. Therefore, even the c-plane can be etched. The PEC etching in the PEC etching step is performed while irradiating with UV light 321 from above the surface 61 of the epi layer 60 which is the c-plane. Thereby, the group III nitride constituting the epi layer 60 is etched from a direction vertical to the surface 61 (that is, in a thickness direction of the epi layer 60).

In contrast, the flattening etching which is not PEC etching is performed as normal wet etching, in which for example, an etching solution such as hydrochloric acid hydrogen peroxide is used. Since it is difficult to etch the c-plane of the group III nitride by normal wet etching, the flat portion 181 of the bottom surface 111 of the recess 110 is not etched, the flat portion 181 containing the c-plane. However, since the protrusion 182 of the bottom surface 111 contains a crystal plane other than the c-plane, it can be etched by ordinary etching. Accordingly, the protrusion 182 can be selectively etched by the flattening etching, with respect to the flat portion 181 of the bottom surface 111 of the recess 110. The flattening etching is to etch a crystal plane other than the c-plane, that is, a crystal plane intersecting the c-plane, and etch the protrusion 182 from a direction that is not vertical to the c-plane (that is, in a direction that intersects the thickness direction of the epi layer 60 (lateral direction)).

By etching the protrusion 182 by flattening etching, the protrusion 182 can be lowered to bring the bottom surface 111 closer to be flat, that is, the protrusion 182 can be brought closer to the c-plane constituting the flat portion 181. When the protrusion 182 is etched and is closer to the c-plane, the etching becomes difficult to progress. Therefore, in the flattening etching step of the present embodiment, it is easy to finish the flattening etching in a state where the protrusion 182 is suppressed from being excessively etched and the bottom surface 111 is substantially flat.

The mask 170 used in the PEC etching step may be removed in the flattening etching step, or may be removed by separately providing a mask removing step for removing the mask 170.

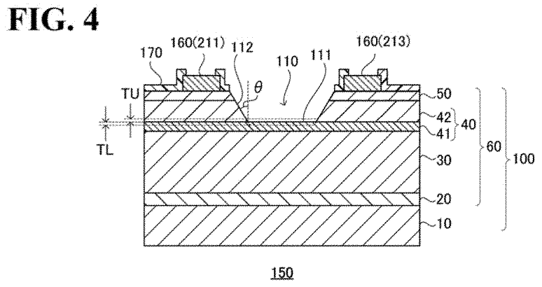

FIG. 4 is a schematic cross-sectional view of the etching target 150, illustrating a state in which the flattening etching step is completed. By removing the protrusion 182, the bottom surface 111 of the recess 110 is flattened.

After the flattening etching step is completed, other steps for completing the HEMT 200 are performed (see FIG. 1(a)). As other steps, a step of forming the gate electrode 212 on the bottom surface 111 of the recess 110, a step of forming the element separation region 230, a step of forming the protective film 220, and the like are performed. In this way, the HEMT 200 is manufactured.

The etching target 150 in a state where the element separation region 230 (an element separation groove in this example) is not formed (see FIG. 2(a)), that is, an embodiment in which a device separation groove is formed after the PEC etching step, is exemplified. However, by forming the element separation groove before the PEC etching step, the etching target 150 with the element separation region 230 formed therein, may be used.

The characteristics of the recess 110 in the HEMT 200 will be further described schematically, with reference to FIG. 4. As described above, in the PEC etching for forming the recess 110 according to the present embodiment, the i-type layer 41 is used as an etching stopper. Therefore, typically (ideally), the recess 110 is formed in such a manner that the overall thickness of the n-type layer 42 is removed and the overall thickness of the i-type layer 41 is arranged below the recess 110.

However, in actual PEC etching, errors may occur, so the thickness of the barrier layer 40 arranged below the recess 110 does not have to exactly match the overall thickness of the i-type layer 41, and the bottom surface 111 of the recess 110 is arranged in the vicinity of the top surface of the i-type layer 41.

For example, the bottom surface 111 of the recess 110 may reach the top surface of the i-type layer 41. In such a case, by removing the overall thickness of the n-type layer 42, the recess 110 with the i-type layer 41 exposed, is formed on the bottom surface 111. The bottom surface 111 is arranged in the vicinity of the top surface of the i-type layer 41 at a position below the top surface. More specifically, the thickness (depth) TL (see FIG. 4) from the top surface of the i-type layer 41 to the bottom surface 111 of the recess 110 is (0 nm or more,) preferably 1 nm or less. In FIG. 4, the bottom surface 111 when located below the top surface of the i-type layer 41 is shown by a broken line.

Further, for example, the bottom surface 111 of the recess 110 does not have to reach the top surface of the i-type layer 41. In such a case, by removing a part of the thickness of the n-type layer 42, the recess 110 with the n-type layer 42 exposed, is formed on the bottom surface 111. The bottom surface 111 is arranged in the vicinity of the top surface of the i-type layer 41 and above the top surface. More specifically, the thickness (depth) TU (see FIG. 4) from the bottom surface 111 of the recess 110 to the top surface of the i-type layer 41 is preferably 1 nm or less (more than 0 nm). In FIG. 4, the bottom surface 111 when located above the top surface of the i-type layer 41 is shown by a broken line.

Further, the bottom surface 111 of the recess 110 formed by PEC etching (and flattening etching) has high flatness. For example, an arithmetic mean roughness (Ra) on the bottom surface 111 is preferably 0.4 nm or less, more preferably 0.3 nm or less, which is measured by observing a 1000 nm square region on the bottom surface 111 of the recess 110 with an atomic force microscope (AFM).

Further, for example, a difference (absolute value of the difference) between an arithmetic mean roughness (Ra) on the surface 61 measured by observing a 1000 nm square region on the surface 61 of the epi layer 60 with AFM, and an arithmetic mean roughness (Ra) on the bottom surface 111 measured by observing a 1000 nm square region on the bottom surface 111 of the recess 110 with AFM, is preferably 0.2 nm or less, more preferably 0.1 nm or less

Further, for example, when a cross section orthogonal to the top surface of the barrier layer 40 (so as to be orthogonal to the edge of the recess 110 in a plan view) and intersecting the bottom surface 111 of the recess 110 is observed with a transmission electron microscope (TEM), a difference between a maximum value and a minimum value (maximum value-minimum value) of a height of the bottom surface 111 (thickness of the barrier layer 40 arranged below the recess 110) in a range of a length of 30 nm or more along the bottom surface 111 in the cross section, is preferably 0.2 nm or less, more preferably 0.1 nm or less.

Further, a side surface 112 of the recess 110 formed by PEC etching (and flattening etching) has a tapered shape whose upper side is inclined outward (in plan view) of the bottom surface 111 of the recess 110. An inclination angle θ (see FIG. 4) of the side surface 112 of the recess 110 with respect to a normal direction of the bottom surface 111 of the recess 110 is, for example, 300 or more, and is, for example, 400 or more. The inclination angle θ is defined as, for example, an average angle of the side surface 112 with respect to the height from the bottom surface 111 of the recess 110 to the edge (the surface 61 of the epi layer 60) of the recess 110.

Dry etching is known as a conventional method for forming a recess serving as a gate recess in a HEMT. However, the crystallinity of the group III nitride that constitutes the bottom surface of the gate recess is deteriorated due to the dry etching for forming the recess, and a halogen element used for the dry etching remains on the bottom surface of the recess. Such deterioration of crystallinity and remained halogen element lead to deterioration of a HEMT performance.

The recess 110 according to the present embodiment is formed by PEC etching (and flattening etching), which is wet etching. Therefore, the deterioration of the crystallinity due to etching on the bottom surface 111 of the recess 110 is suppressed as compared with the deterioration of the crystallinity assumed when dry etching is used. Thereby, a band edge peak intensity of a photoluminescence emission spectrum on the bottom surface 111 of the recess 110 preferably has an intensity of 90% or more with respect to a band edge peak intensity of a photoluminescence emission spectrum on the surface 61 of the epi layer 60 (which is an area where etching is not applied).

Further, in the present embodiment, the remained halogen element on the bottom surface 111 of the recess 110 is suppressed as compared with the remained halogen element assumed when dry etching is used. For example, in a secondary ion mass spectrometry (SIMS) measurement, a concentration of the halogen element due to PEC etching (and flattening etching), which is wet etching for forming the recess 110, is considered to be preferably a lower limit or less of detection. The concentration of the halogen element (for example, chlorine (Cl)) on the bottom surface 111 of the recess 110 is preferably less than 1×10¹⁵/cm³, more preferably less than 5×10¹⁴/cm³, and further more preferably less than 2×10¹⁴/cm³.

In this way, in the HEMT 200 according to the present embodiment, the deterioration of the crystallinity and remaining of the halogen element due to etching for forming the recess 110, are suppressed. Therefore, deterioration of a performance of the HEMT 200 due to etching for forming the recess 110, can be suppressed.

As described above, the present embodiment provides a suitable technique for forming the recess (gate recess) 110 by PEC etching in the semiconductor device (HEMT) 200 containing a group III nitride. More specifically, the recess 110 can be formed by forming the barrier layer 40 having a laminated structure of the i-type layer 41 and the n-type layer 42 and performing PEC etching, with the i-type layer 41 as an etching stopper.

### Experimental Example

Next, an experimental example relating to PEC etching and flattening etching will be described. In this experimental example, a wafer having the following substrate and epi layer was used. As the substrate, a semi-insulating SiC substrate was used. As the epi layer, a laminated structure of a nucleation layer containing AlN, a channel layer containing GaN and having a thickness of 0.75 μm, a barrier layer containing AlGaN and having a thickness of 24 nm, and a cap layer containing GaN and having a thickness of 5 nm, was formed. A thickness (depth) from the top surface of the cap layer to the bottom surface of the barrier layer is 29 nm. As the barrier layer, a laminated structure of a lower layer (i-type layer) containing i-type AlGaN and having an Al composition of 0.22 and a thickness of 5 nm, and an upper layer (n-type layer) containing n-type AlGaN and having an Al composition of 0.22 and a thickness of 19 nm, was formed. Si was added to the upper layer (n-type layer) as an n-type impurity at a concentration of 1×10¹⁸/cm³.

A recess was formed on the epi layer by PEC etching. With 0.025M K₂S₂O₈ aqueous solution used as an etching solution, the PEC etching was performed for 120 minutes while irradiating with UV light having a wavelength of 260 nm at an intensity of 3.8 mW/cm². A wafer placement depth L was 5 mm. The mask contains silicon oxide and the cathode pad contains titanium.

After PEC etching, the bottom of the recess was flattened by flattening etching. The flattening etching was performed for 10 minutes, with hydrochloric acid hydrogen peroxide (for example, a mixture of 30% HCl and 30% H₂O₂ at a ratio of 1:1) as an etching solution.

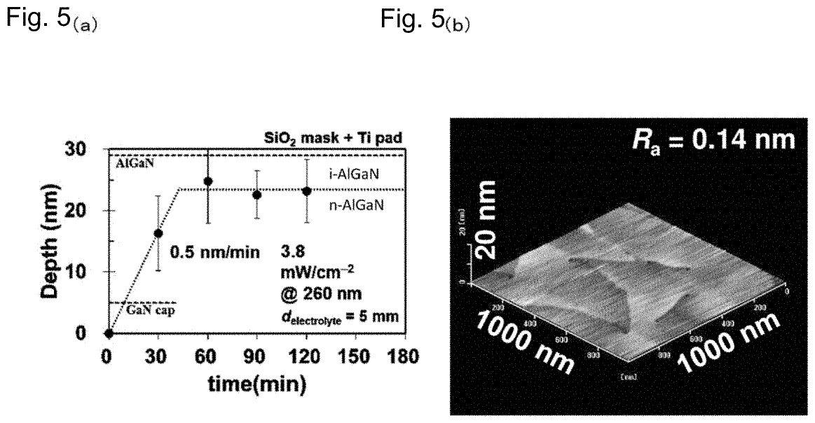

FIG. 5(a) is a graph showing the relationship between an etching time and an etching depth in PEC etching. The horizontal axis shows the etching time, and the vertical axis shows the etching depth. The etching depth becomes deeper in proportion to the etching time, from a start of etching to about 40 minutes. The etching depth is constant, after about 40 minutes have passed from the start of etching. That is, it is found that PEC etching automatically stopped about 40 minutes after the start of etching.

A difference between a depth (about 24 nm) at which PEC etching is stopped and a depth (29 nm) of the bottom surface of the barrier layer (denoted as “AlGaN”) is about 5 nm. From this fact, it is understood that PEC etching stops in the vicinity of the top surface of the lower layer of the barrier layer at a point where the overall thickness of the upper layer of the barrier layer (denoted as “n-AlGaN”) is removed, with the lower layer of the barrier layer (denoted as “i-AlGaN”) serving as an etching stopper.

An observation was performed to a 1000 nm square region on each of the surface of the epi layer before PEC etching (hereinafter referred to as the epi layer surface), the bottom surface of the recess formed by PEC etching and not flattened (hereinafter referred to as an unflattened bottom surface), and the bottom surface of the recess that has been flattened after PEC etching (hereinafter referred to as a flattened bottom surface).

FIG. 5(b) is an AFM image of the surface of the epi layer. An arithmetic mean roughness (Ra) on the surface of the epi layer is 0.14 nm, which is measured by observing the surface with AFM. Since the epi layer is desired to have high crystallinity, Ra on the surface of the epi layer is preferably 0.4 nm or less, more preferably 0.3 nm or less, and further preferably 0.2 nm or less.

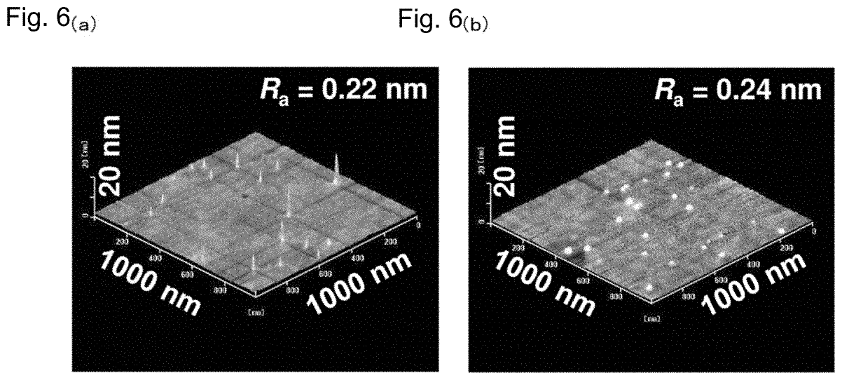

FIG. 6(a) is an AFM image of the unflattened bottom surface. On the unflattened bottom surface, protrusions are observed at positions corresponding to the dislocations. There is a tendency that the heights of the plurality of protrusions distributed on the unflattened bottom surface are not constant. The height of a maximum protrusion is more than 10 nm.

Ra obtained by AFM measurement on the unflattened bottom surface is 0.22 nm. The Ra on the surface of the epi layer is, for example, 0.14 nm, while the Ra on the unflattened bottom surface is, for example, 0.22 nm. Although the unflattened bottom surface has the protrusions, Ra is, for example, twice or less the Ra on the surface of the epi layer, and do not increase so much. The reason is considered that PEC etching was performed so that a flat portion that occupies most of an area of the unflattened bottom surface has high flatness, that is, a high flatness that the epi layer surface had is almost not impaired in the flat portion. Ra of the unflattened bottom surface is preferably 0.4 nm or less, more preferably 0.3 nm or less.

FIG. 6(b) is an AFM image of the flattened bottom surface. On the flattened bottom surface, the protrusions observed on the unflattened bottom surface were not clearly observed, and it is found that the bottom surface of the recess is flattened. On the flattened bottom surface, the positions where the protrusions are presumed to have been formed, that is, the positions corresponding to the dislocations are observed as a bright region separately from the flat portion.

Ra obtained by AFM measurement on the flattened bottom surface is 0.24 nm. The Ra of the unflattened bottom surface is, for example, 0.22 nm, while the Ra of the flattened bottom surface is slightly larger, for example, 0.24 nm. Such a difference is considered to be an error caused by a difference between a measurement area of the unflattened bottom surface and a measurement area of the flattened bottom surface, and Ra on the unflattened bottom surface and Ra on the flattened bottom surface are considered to be about the same. It can be said that it is difficult to clearly distinguish between the unflattened bottom surface and the flattened bottom surface only by Ra. From the AFM image of the flattened bottom surface, it is found that the protrusions can be selectively etched by the flattening etching without deteriorating the flatness of the flat portion. Ra on the flattened bottom surface is preferably 0.4 nm or less, more preferably 0.3 nm or less.

The flattened bottom surface, which is the bottom surface of a finally obtained recess, has such high flatness. A difference (an absolute value of the difference) between Ra on the epi layer surface and Ra on the flattened bottom surface (or Ra on the unflattened plane) is (0 nm or more), preferably 0.2 nm or less, and more preferably 0.1 nm or less.

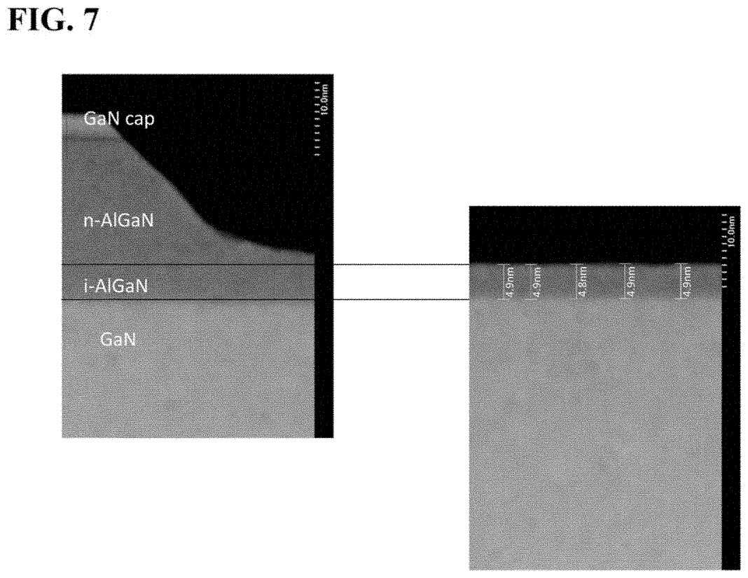

FIG. 7 is a cross-sectional image of the epi layer in which the recess is formed, which is observed by TEM. The cross-sectional image is a cross-sectional image that is orthogonal to the top surface of the barrier layer and intersects the bottom surface of the recess (so as to be orthogonal to the edge of the recess in plan view). In FIG. 7, the channel layer is denoted as “GaN”, the lower layer of the barrier layer (i-type layer) is denoted as “i-AlGaN”, the upper layer of the barrier layer (n-type layer) is denoted as “n-AlGaN”, and the cap layer is denoted as “GaN cap”. A left side portion of FIG. 7 shows a cross-sectional image of a side surface portion of the recess, and a right side portion of FIG. 7 shows a cross-sectional image of a bottom surface portion of the recess.

The flatness of the bottom surface of the recess is also confirmed by observing it with TEM. The cross-sectional image of the bottom surface shows a range (30 nm or more) with a length of about 35 nm in the in-plane direction of the bottom surface. The thickness of the barrier layer (remaining thickness of the barrier layer) arranged below the recess is measured at 5 points and is 4.9 nm at 4 points and 4.8 nm at 1 point. This reveals that the difference between the maximum and minimum values of the remaining thickness of the barrier layer in the above range, in other words, the difference between the maximum and minimum values of the height of the bottom surface of the recess (the top surface of the remaining thickness of the barrier layer) in the above range, is as small as 0.1 nm, and it is found that high uniformity of the remaining thickness of the barrier layer, that is, high flatness of the bottom surface of the recess is obtained. Thus, the difference between the maximum and minimum values (maximum value-minimum value) of the height of the bottom surface of the recess or the remaining thickness of the barrier layer is preferably 0.2 nm or less, and more preferably 0.1 nm or less, in a range of length 30 nm or more along the bottom surface of the cross-sectional image of the bottom surface of the recess observed by TEM.

From the cross-sectional image of the side surface portion, it is found that the side surface of the recess has a tapered shape in which the upper side is inclined outward (in a plan view) of the bottom surface of the recess. An inclination angle of the side surface is shown by an inclination angle from a normal direction of the bottom surface of the recess (see FIG. 4). In this example, a change in the inclination angle is observed such that the inclination angle in a lower portion of the side surface is larger (approaching 90°) than the inclination angle in an upper portion of the side surface. It can be said that the inclination angle of the upper portion of the side surface is about 45°, and an overall inclination angle of the side surface, which is an average of the inclination angles from the height of the bottom surface of the recess to the height of the edge of the recess, is 45° or more. One characteristic of the tapered shape on the side surface of the recess is that the inclination angle is, for example, 30° or more, and for example, 40° or more.

### Other Embodiments

The embodiment of the present disclosure has been specifically described above. However, the present disclosure is not limited to the above-described embodiment, and various modifications, improvements, combinations, and the like can be made without departing from the gist thereof.

For example, the above-described embodiment is an embodiment in which the cathode pad 160 is used as at least one of the source electrode 211 and the drain electrode 213 of the HEMT 200. However, the cathode pad 160 may be a conductive member different from the source electrode 211 or the drain electrode 213 of the HEMT 200.

Further for example, the above-described embodiment is an embodiment in which wet etching (not PEC etching) is used as the flattening etching in which an acidic or alkaline etching solution is used, that is, it is an embodiment of chemically etching the protrusion 182. However, the mechanism of the flattening etching is not particularly limited as long as the protrusion 182 is etched so that the bottom surface 111 is flattened. Therefore, the flattening etching may be performed by etching by a mechanism other than chemical etching. By combining etching of a plurality of mechanisms, flattening etching may be performed more effectively.

The flattening etching may be performed, for example, by mechanically removing the protrusion 182, and as the mechanical flattening etching, for example, bubbling cleaning may be used, or, for example, scrub cleaning may be used. An example of the etching solution (cleaning solution) for the bubbling cleaning includes hydrochloric acid hydrogen peroxide exemplified in the above-described embodiment. When the protrusion 182 is etched with hydrogen peroxide, bubbles are violently generated. Therefore, the protrusion 182 can be destroyed and removed by an impact caused by the generation of the bubbles. It can be said that hydrochloric acid hydrogen peroxide is an etching solution that chemically and mechanically etches the protrusion 182. When performing flattening etching, an action of mechanically etching the protrusion 182 may be enhanced by performing at least one of generating a flow (movement) in the etching solution 401 or applying vibration (for example, ultrasonic vibration) to the etching solution 401.

Further for example, the above-described embodiment is an embodiment in which flattening etching is performed to flatten the bottom surface 111 of the recess 110 after completing the PEC etching for forming the recess 110. However, the flattening etching may be performed before completing the PEC etching for forming the recess 110, that is, at a stage where the recess 110 is formed to an intermediate depth, and then the PEC etching may be performed again to make the recess 110 deeper. That is, the PEC etching step and the flattening etching step may be repeated alternately, and the flattening etching step may be performed a plurality of times as needed.

In addition, the above-described embodiment exemplifies a technique for forming the recess (gate recess) 110 on the barrier layer 40 of the HEMT 200 by PEC etching. However, the technique may be used as a technique for forming a structure not limited to a semiconductor device. That is, the technique may be widely used as a technique for obtaining a structure in which recess is formed in the laminated structure by applying PEC etching to the laminated structure including the lower layer (i-type layer) and the upper layer (n-type layer) similar to the barrier layer 40 described above, with the lower layer (i-type layer) as an etching stopper. The “recess” indicate a region subjected to PEC etching in the laminated structure.

### <Preferable Aspects of the Present Disclosure>

Preferable aspects of the present disclosure will be described hereafter.

### (Supplementary Description 1)

There is provided a semiconductor device, including:

a substrate;

a group III nitride layer on the substrate, the group III nitride layer containing group III nitride; and

a recess on the group III nitride layer,

the group III nitride layer including:

a channel layer, and

a barrier layer on the channel layer, thereby forming a two-dimensional electron gas in the channel layer,

the barrier layer including:

a first layer containing aluminum gallium nitride (preferably containing i-type aluminum gallium nitride), and

a second layer on the first layer, the second layer containing (n-type) aluminum gallium nitride added with an n-type impurity,

wherein the recess is formed by removing all or a part of a thickness of the second layer, and at least a part of a thickness of the first layer is arranged below the recess.

### (Supplementary Description 2)

There is provided the semiconductor device according to supplementary description 1, wherein the recess is formed by removing an overall thickness of the second layer.

### (Supplementary Description 3)

There is provided the semiconductor device according to supplementary description 2, wherein a thickness from a top surface of the first layer to a bottom surface of the recess is 1 nm or less.

### (Supplementary Description 4)

There is provided the semiconductor device according to supplementary description 1, wherein the recess is formed by removing a part of the thickness of the second layer, and a thickness from a bottom surface of the recess to a top surface of the first layer is 1 nm or less.

### (Supplementary Description 5)

There is provided the semiconductor device according to any one of supplementary descriptions 1 to 4, wherein an arithmetic mean roughness (Ra) on a bottom surface is preferably 0.4 nm or less, more preferably 0.3 nm or less, which is measured by observing a 1000 nm square region on the bottom surface of the recess with an atomic force microscope.

### (Supplementary Description 6)

There is provided the semiconductor device according to any one of supplementary descriptions 1 to 5, wherein a difference between an arithmetic mean roughness (Ra) of a 1000 nm square region on a surface of the group III nitride layer measured by observing the surface with an atomic force microscope and an arithmetic mean roughness (Ra) of a 1000 nm square region on a bottom surface of the recess measured by observing the bottom surface with an atomic force microscope, is preferably 0.2 nm or less, more preferably 0.1 nm or less.

### (Supplementary Description 7)

There is provided the semiconductor device according to any one of supplementary descriptions 1 to 6, wherein when a cross section orthogonal to a top surface of the barrier layer and intersecting a bottom surface of the recess is observed with a transmission electron microscope, a difference between a maximum value and a minimum value of a height of the bottom surface of the recess (a thickness of the barrier layer arranged below the recess) is preferably 0.2 nm or less, more preferably 0.1 nm or less, in a range of a length of 30 nm or more along the bottom surface in the cross section.

### (Supplementary Description 8)

There is provided the semiconductor device according to any one of supplementary descriptions 1 to 7, wherein a side surface of the recess has a tapered shape in which an upper side is inclined outward of a bottom surface of the recess.

### (Supplementary Description 9)

There is provided the semiconductor device according to supplementary description 8, wherein an inclination angle of the side surface of the recess with respect to a normal direction of the bottom surface of the recess is 300 or more (or 40° or more).

### (Supplementary Description 10)

There is provided the semiconductor device according to any one of supplementary descriptions 1 to 9, wherein a band edge peak intensity of a photoluminescence emission spectrum on a bottom surface of the recess has an intensity of 90% or more, with respect to a band edge peak intensity of a photoluminescence emission spectrum on a surface of the group III nitride layer.

### (Supplementary Description 11)

There is provided the semiconductor device according to any one of supplementary descriptions 1 to 10, wherein a concentration of a halogen element on a bottom surface of the recess is preferably less than 1×10¹⁵/cm³, more preferably less than 5×10¹⁴/cm³, and further preferably less than 2×10¹⁴/cm³.

### (Supplementary Description 12)

There is provided the semiconductor device according to any one of supplementary descriptions 1 to 11, wherein a concentration of n-type impurity in the second layer is 1×10¹⁷/cm³ or more and less than 1×10¹⁹/cm³.

### (Supplementary Description 13)

There is provided the semiconductor device according to any one of supplementary descriptions 1 to 12, wherein an aluminum composition x in AlₓGa₁₋ₓN constituting the first layer is in a range of 0.1≤x≤0.3, and an aluminum composition y in Al_{y}Ga_{1-y}N constituting the second layer is in a range of 0.1≤x≤0.3.

### (Supplementary Description 14)

There is provided the semiconductor device according to any one of supplementary descriptions 1 to 13, wherein an aluminum composition of aluminum gallium nitride constituting the first layer and an aluminum composition of aluminum gallium nitride constituting the second layer are equivalent.

### (Supplementary Description 15)

There is provided the semiconductor device according to any one of supplementary descriptions 1 to 14, wherein a thickness of the first layer is 2 nm or more and 10 nm or less.

### (Supplementary Description 16)

There is provided the semiconductor device according to any one of supplementary descriptions 1 to 15, wherein a thickness of the second layer is 5 nm or more and 90 nm or less.

### (Supplementary Description 17)

There is provided the semiconductor device according to any one of supplementary descriptions 1 to 16, including: a source electrode, a gate electrode, and a drain electrode, wherein the gate electrode is formed on a bottom surface of the recess.

### (Supplementary Description 18)

There is provided a method for manufacturing a structure, the structure including:

a substrate;

a group III nitride layer on the substrate, the group III nitride layer containing group III nitride, and

a recess on the group III nitride layer,

the group III nitride layer including:

a channel layer, and

a barrier layer on the channel layer, thereby forming a two-dimensional electron gas in the channel layer,

the barrier layer including:

a first layer containing aluminum gallium nitride (preferably containing i-type aluminum gallium nitride), and

a second layer on the first layer, the second layer containing (n-type) aluminum gallium nitride added with an n-type impurity,

wherein the recess is formed by removing all or a part of a thickness of the second layer, and at least a part of a thickness of the first layer is arranged below the recess,

the method including

forming the recess by etching the second layer by photoelectrochemical etching, with the first layer as an etching stopper.

### (Supplementary Description 19)

There is provided the method for manufacturing a structure according to supplementary description 18, wherein flattening etching is performed to remove protrusions which are undissolved portions in the photoelectrochemical etching.

### (Supplementary Description 20)

There is provided a structure, including:

a laminated structure of a first layer containing aluminum gallium nitride (preferably containing i-type aluminum gallium nitride) and a second layer on the first layer, the second layer containing (n-type) aluminum gallium nitride added with an n-type impurity, and

a recess on the laminated structure,

wherein the recess is formed by removing all or a part of a thickness of the second layer, and at least a part of a thickness of the first layer is arranged below the recess.

### (Supplementary Description 21)

There is provided a method for manufacturing a structure, the structure including:

a laminated structure of a first layer containing aluminum gallium nitride (preferably containing i-type aluminum gallium nitride) and a second layer on the first layer, the second layer containing (n-type) aluminum gallium nitride added with an n-type impurity, and

a recess on the laminated structure,

wherein the recess is formed by removing all or a part of a thickness of the second layer, and at least a part of a thickness of the first layer is arranged below the recess,

the method including:

forming the recess by etching the second layer by photoelectrochemical etching, with the first layer as an etching stopper.

### DESCRIPTION OF SIGNS AND NUMERALS

10 . . . substrate, 20 . . . nucleation layer, 30 . . . channel layer, 40 . . . barrier layer, 41 . . . lower layer (i-type layer), 42 . . . (barrier layer) upper layer (n-type layer), 50 . . . cap layer, 60 . . . epi layer, 61 . . . surface (of epi layer), 62 . . . region to be etched, 100 . . . wafer, 110 . . . recess, 111 . . . bottom surface (of recess), 112 . . . side surface (of recess), 150 . . . etching target, 160 . . . cathode pad, 170 . . . mask, 181 . . . flat portion (at the bottom of the recess), 182 . . . protrusion (at the bottom of the recess), 200 . . . semiconductor device (HEMT), 211 . . . source electrode, 212 . . . gate electrode, 213 . . . drain electrode, 220 . . . protective film, 230 . . . element separation region, 300 . . . PEC etching device, 301 . . . etching solution, 310 . . . container, 320 . . . light source, 321 . . . light, 400 . . . flattening etching device, 401 . . . etching solution, 410 . . . container

1. A semiconductor device, comprising:
a substrate;
a group III nitride layer on the substrate, the group III nitride layer containing group III nitride; and
a recess on the group III nitride layer,
the group III nitride layer including:
a channel layer, and
a barrier layer on the channel layer, thereby forming a two-dimensional electron gas in the channel layer,
the barrier layer including:
a first layer containing aluminum gallium nitride, and
a second layer on the first layer, the second layer containing aluminum gallium nitride added with an n-type impurity,
wherein the recess is formed by removing all or a part of a thickness of the second layer, and at least a part of a thickness of the first layer is arranged below the recess.

2. The semiconductor device according to claim 1, wherein the recess is formed by removing an overall thickness of the second layer.

3. The semiconductor device according to claim 2, wherein a thickness from a top surface of the first layer to a bottom surface of the recess is 1 nm or less.

4. The semiconductor device according to claim 1, wherein the recess is formed by removing a part of the thickness of the second layer, and a thickness from a bottom surface of the recess to a top surface of the first layer is 1 nm or less.

5. The semiconductor device according to claim 1, wherein an arithmetic mean roughness (Ra) on a bottom surface is 0.4 nm or less, which is measured by observing a 1000 nm square region on the bottom surface of the recess with an atomic force microscope.

6. The semiconductor device according to claim 1, wherein a difference between an arithmetic mean roughness (Ra) of a 1000 nm square region on a surface of the group III nitride layer measured by observing the surface with an atomic force microscope and an arithmetic mean roughness (Ra) of a 1000 nm square region on a bottom surface of the recess measured by observing the bottom surface with an atomic force microscope, is 0.2 nm or less.

7. The semiconductor device according to claim 1, wherein when a cross section orthogonal to a top surface of the barrier layer and intersecting a bottom surface of the recess is observed with a transmission electron microscope, a difference between a maximum value and a minimum value of a height of the bottom surface of the recess is 0.2 nm or less, in a range of a length of 30 nm or more along the bottom surface in the cross section.

8. The semiconductor device according to claim 1, wherein a side surface of the recess has a tapered shape in which an upper side is inclined outward of a bottom surface of the recess.

9. The semiconductor device according to claim 8, wherein an inclination angle of the side surface of the recess with respect to a normal direction of the bottom surface of the recess is 30° or more.

10. The semiconductor device according to claim 1, wherein a band edge peak intensity of a photoluminescence emission spectrum on a bottom surface of the recess, has an intensity of 90% or more, with respect to a band edge peak intensity of a photoluminescence emission spectrum on a surface of the group III nitride layer.

11. The semiconductor device according to claim 1, wherein a concentration of a halogen element on a bottom surface of the recess is less than 1×10¹⁵/cm³.

12. The semiconductor device according to claim 1, wherein an aluminum composition of aluminum gallium nitride constituting the first layer and an aluminum composition of aluminum gallium nitride constituting the second layer are equivalent.

13. A method for manufacturing a structure, the structure including:
a laminated structure of a first layer containing aluminum gallium nitride and a second layer on the first layer, the second layer containing aluminum gallium nitride added with an n-type impurity, and
a recess on the laminated structure,
wherein the recess is formed by removing all or a part of a thickness of the second layer, and at least a part of a thickness of the first layer is arranged below the recess,
the method comprising:
forming the recess by etching the second layer by photoelectrochemical etching, with the first layer as an etching stopper.
